(19) United States
(12) Patent Application Publication
(10) Pub. No.: US 2008/0084159 A1
(43) Pub. Date: Apr. 10, 2008

(54) Organic Double-Sided Light-Emitting Diode with a Light Extraction Dielectric Layer

(76) Inventors: Christophe Fery, Rennes (FR); Eric Marcellin-Dibon, Vaucresson (FR)

Correspondence Address: Joseph J. Laks;Thomson Licensing LLC, 2 Independence Way, Patent Operations, PO Box 5312, PRINCETON, NJ, 08543, US

(21) Appl. No.: 11/793,581

(22) PCT Filed: Dec. 21, 2005
(86) PCT No.: PCT/EP05/57064

§ 371 Date: Jun. 20, 2007

(30) Foreign Application Priority Data
Dec. 21, 2004 (FR) 0453130

(51) Int. Cl. H01J 1/62

(52) U.S. Cl. 313/504

(57) ABSTRACT

Diode comprising:
an organic electroluminescent layer (4) interposed between a lower transparent electrode (5) and an upper transparent electrode (3); and
a dielectric layer (6,2) placed in contact with each electrode (5, 3) opposite the organic electroluminescent layer (4), which is adapted so as to obtain, in combination with said electrode (6, 2), maximum reflectivity of the emitted light. Such a structure optimizes the light extraction and therefore the luminous yield. Displays or illumination panels comprising an array of these diodes.

The invention relates to an organic light-emitting diode capable of emitting light via two opposed faces, comprising:
a transparent or semitransparent substrate;
an organic electroluminescent layer capable of emitting light, deposited on this substrate, this layer being interposed between a lower electrode and an upper electrode, each electrode being transparent or semitransparent.

This is therefore what is called a top-emitting and bottom-emitting diode. Such diodes may have a conventional structure, in which case the upper electrode is a cathode, or the reverse structure, in which case the upper electrode is an anode.

The invention also relates to arrays of these diodes, especially those that are contained in illumination panels or in displays, especially video image displays.

Document U.S. Pat. No. 6,762,436 describes a diode and a display of this type.

Documents EP 1 076 368, EP 1 439 589 and EP 1 443 572 describe diodes emitting via only one side, where a dielectric layer having the lower transparent electrode or the upper transparent electrode is joined (see FIG. 4d in EP 1 439 589). This dielectric layer (reference 22, made of ZnS: 20% SiO₂ material) has the function of reducing the absorption of the light emitted through the transparent or semitransparent electrode to which it is joined.

According to said documents, this absorption-reducing dielectric layer is adapted, as indicated below, to the metal layer of the electrode to which it is joined, both in terms of index and thickness, in order to improve extraction of the emitted light.

Document EP 1 076 368 indicates (see in particular §17) that the addition of a dielectric layer on a relatively thick (20 nm) metal layer allows the transmittance of the electrode to be doubled (passing from 30% to 60%).

Examples and tables of data also illustrate this point in document EP 1 439 589:
Example 2 and Table 2 for a bottom-emitting diode: silver transparent anode; with an almost identical silver thickness (17.5 nm and 18.5 nm), the addition of an absorption-reducing dielectric (ITO) layer increases the luminance of the diode by 6.5%; and

Example 4 and Table 4 for a top-emitting diode: silver transparent upper cathode; although the thickness of the silver is increased by 50% (20.3 nm against 13.7 nm in the absence of the dielectric layer), the luminance is increased by 14% thanks to a 61.4 nm dielectric layer made of ZnS—20% SiO₂.

It is an object of the invention to improve the luminance efficiency of organic diodes emitting via two opposed sides. According to the invention, a dielectric layer is joined to each of the electrodes and each stack consisting of an electrode with its dielectric layer is adapted so as no longer to obtain minimum absorption but maximum reflectivity, while keeping sufficiently transparent electrodes in order to limit absorption losses. Thanks to this high reflectivity, the diode can benefit from an optical cavity effect without absorption losses between the two electrodes, although these are nevertheless transparent or semitransparent. It should be noted that document U.S. Pat. No. 6,124,024, although specifying a number of conditions relating to the thickness of the layers, nowhere teaches maximum reflectivity combined with intrinsic transparency of the electrodes. It should be noted that document U.S. Pat. No. 5,652,067 does teach the insertion of a lower dielectric layer between the substrate and the lower electrode, but this layer is transparent to ultraviolet radiation and not to the light emitted by the diode, and that its thickness is not adapted so as to obtain, in combination with the lower electrode, maximum reflectivity.

More precisely, the subject of the invention is an organic light-emitting diode capable of emitting light via two opposed faces, comprising:
a transparent or semitransparent substrate;
an organic electroluminescent layer capable of emitting light, deposited on this substrate, this layer being interposed between a lower electrode and an upper electrode, each electrode being transparent or semitransparent; and
a lower dielectric layer interposed between the substrate and said lower electrode, and an upper dielectric layer covering said upper electrode.

The upper dielectric layer therefore covers the upper electrode on the opposite side from the electroluminescent layer and can therefore act as interface with the air or with another ambient medium, in which case it also preferably serves as an encapsulation and protection layer, by protecting against the risks of the organic layer being degraded by oxygen or water vapor from the air. Both the lower and upper dielectric layers are not scattering layers as in document EP 1 406 474, but transparent layers preferably having an intrinsic transmittance for the emitted light of 85% or higher.

When an electric current flows between the lower electrode and the upper electrode through the electroluminescent layer, the latter emits light.

Preferably, the material of the lower dielectric layer and that of the upper dielectric layer have an index greater than 1.6.

Preferably, the lower electrode comprises a lower conducting layer, which is in contact with the lower dielectric layer, and the upper electrode comprises an upper conducting layer which is in contact with the upper dielectric layer.

Preferably, the material and the thickness d₂ of said upper dielectric layer and the material and the thickness d₃ of said upper conducting layer are adapted in order for the reflectivity of said emitted light evaluated on this stack of layers to be approximately a maximum.

Preferably, the material and the thickness d₆ of said lower dielectric layer and the material and the thickness d₅ of said lower conducting layer are adapted in order for the reflectivity of said emitted light evaluated on this stack of layers to be approximately a maximum.

The reflectivity of the stack of layers involves an interference effect between these nevertheless intrinsically transparent or semitransparent layers, this interference effect being adapted for obtaining a high reflectivity. Thanks to the transparency, there is therefore little absorption loss, and thanks to this high reflectivity, obtained by the interference effect, the optical cavity between the electrodes is optimized and the light extraction improved.

Since the material and the thickness (d₅ and/or d₃) of the lower and/or upper conducting layer are for example fixed, especially based on low-resistivity criteria, the curve giving the variation of the reflectivity on this stack of the emitted light as a function of the thickness (d₆ and/or d₂) of the corresponding lower or upper dielectric layer exhibits minima and maxima, which reflect the interference phenomena at the interfaces. According to the invention, a dielectric layer thickness (d₆ and/or d₂) corresponding to a maximum of this curve is chosen.

By optimizing the two stacks in this way, an optical cavity is obtained between the two electrodes, this being optimal for light extraction.

Preferably:
the intrinsic transmittance of said light emitted from said lower conducting layer is equal to or greater than 85%, this corresponding, for an ITO layer, to a limit thickness of 150 nm; and
the intrinsic transmittance of said light emitted from said upper conducting layer is equal to or greater than 85%, this corresponding, for an ITO layer, to a limit thickness of 150 mm.

The term “intrinsic transmittance” is understood to mean the transmittance, evaluated independently of the interference effects, of the layer itself or of the neighboring layers.

To summarize, the organic light-emitting diode according to the invention comprises:
an organic electroluminescent layer capable of emitting light, which layer is interposed between a transparent or semitransparent lower electrode and a transparent or semitransparent upper electrode; and
a dielectric layer placed in contact with each electrode on the opposite side from the organic electroluminescent layer, which is adapted so as to obtain, in combination with said electrode, maximum reflectivity of said emitted light.

Preferably, the material of the upper conducting layer is identical to the material of the lower conducting layer.

According to another embodiment, said organic electroluminescent layer preferably comprises an emissive organic sublayer and at least one nonemissive upper organic sublayer which is interposed between the upper electrode and said emissive sublayer and the thickness of the nonemissive upper organic sublayer(s) is/are adapted so that the distance zᵤₚ separating approximately the middle, in the thickness, of said emissive organic sublayer from said upper electrode approximately satisfies the equation:

$${z}_{up} = \frac{λ}{2 {n}_{4}} ( r - \frac{{ϕ}_{up}}{2 π} )$$

where r is any integer;
where λ is said wavelength close to a maximum emittance of the emitted light and n₄ is the average index of the organic electroluminescent layer at this wavelength; and
where φᵤₚ is the phase shift of a ray of emitted light, after reflection of the upper electrode.

This equation expresses the constructive interference between the emitted light and the light reflected off the upper electrode.

Preferably, according to this embodiment, the organic electroluminescent layer comprises an emissive organic sublayer and at least one nonemissive lower organic sublayer which is interposed between the lower electrode and said emissive sublayer and the thickness of the nonemissive lower organic sublayer(s) is/are adapted so that the distance z_{low} approximately separating the middle, in the thickness, of said emissive organic sublayer from said lower electrode approximately satisfies the equation:

$${z}_{low} = \frac{λ}{2 {n}_{4}} ( q - \frac{{ϕ}_{low}}{2 π} )$$

where q is any integer;
where λ is said wavelength-close to a maximum emittance of the emitted light and n₄ is the average index of the organic electroluminescent layer at this wavelength; and
where φ_{low} is a phase shift of a ray of emitted light, after reflection of the lower electrode.

This equation expresses the constructive interference between the emitted light and the light reflected off the lower electrode.

In general, the nonemissive lower organic sublayer or sublayers are adapted for the injection and/or transport of carriers of a first type and the nonemissive upper organic sublayer or sublayers are adapted for injection and/or transport of carriers of a second type, the carrier types corresponding to electrons and holes respectively.

Preferably, the material of said upper dielectric layer is identical to the material of said lower dielectric layer.

Preferably, the thickness d₄ of said organic electroluminescent layer is adapted so as to obtain constructive interference of the emitted light between the lower electrode and the upper electrode.

This constructive interference advantageously promotes extraction of the light emitted through the two electrodes, thereby improving the luminous efficiency of the diode.

Another subject of the invention is an image display or an illumination panel comprising a plurality of diodes according to the invention, characterized in that these diodes are supported by the same substrate.

Preferably, said plurality forms a two-dimensional array of diodes, the diagonal of which is less than 40 cm. Since the size of the display is small, good display uniformity is obtained over the entire width and entire height of this display.

Preferably, said upper electrode is common to the plurality of said diodes.

The invention will be more clearly understood on reading the following description, given by way of nonlimiting example and with reference to the appended figures in which:

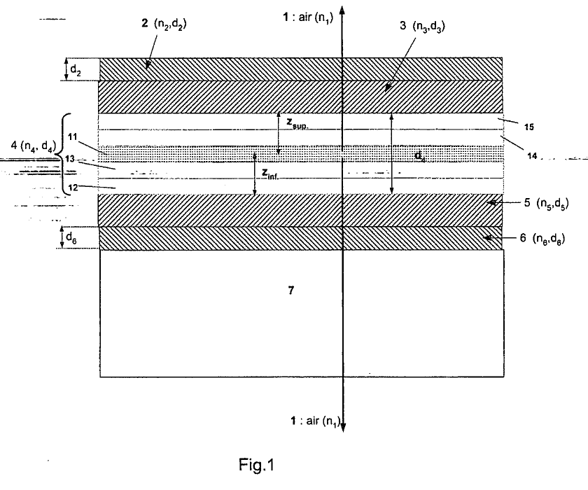

FIG. 1 is a schematic sectional view of an assembly comprising a diode according to one embodiment of the invention; and

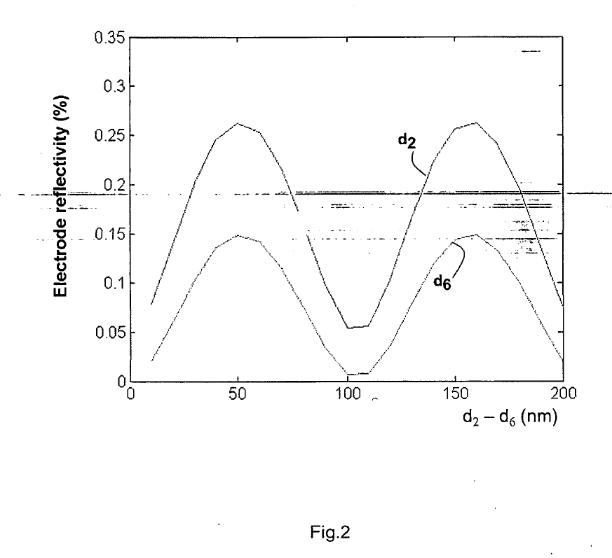

FIG. 2 depicts the variation in light reflectivity in the stock consisting of each electrode with its dielectric layer, according to the embodiment shown in FIG. 1, as a function of the thickness (in nm) of this dielectric layer.

One embodiment of a diode or of an array of diodes according to the invention will now be described, with a few nonlimiting variants, and also a few steps in its manufacture, with reference to FIG. 1.

The manufacture starts with a substrate 7, for example a transparent glass plate or a transparent or semitransparent active matrix comprising drive circuits for the diodes. Document US-2004-155846 describes an example of a transparent active matrix of the prior art. This transparent or semitransparent substrate is provided with a transparent or semitransparent lower electrode or array of lower electrodes intended to serve as cathode(s), each electrode being connected, where appropriate, to an output of a control circuit on the substrate. Here the lower electrodes are formed by a conducting lower layer 5 made of ITO (Indium Tin Oxide) with a thickness d₅=150 nm. Before this ITO layer is deposited, a dielectric layer 6 made of zinc selenide (ZnSe) is deposited, the thickness d₆ of said layer being determined as follows.

Owing to the small thickness of ITO, here 150 nm, for the lower conducting layer 5, the transmittance of the lower electrodes is equal to or greater than 85% for the emitted light. This ITO transmittance data is data from the prior art, for example in the thesis by David Vaufrey published in July 2003, and defended at the Electronics, Optoelectronics and Microsystems Laboratory of the Ecole Centrale in Lyons, France. Transmittance data relating to ITO has also been found in the article entitled “The improvement of ITO film with high work function on OLED applications”, by Ping-Wei Tzeng et al., published within the context of IDMC 2005 (pages 711 to 713 of the Annals).

In FIG. 2, the curve referenced “d₆” shows the variation of the reflectivity of the stack of layers 5 and 6 as a function of the thickness d₆ (in nm) of the layer 6 and this curve is used to choose a value d₆=50 nm corresponding approximately to a maximum of this curve. The reflectivity of the stack of these layers is measured at a wavelength of 550 nm, which corresponds approximately to a maximum emittance of the organic electroluminescent layer that will be deposited in order to form the diode.

Deposited, in a manner known per se, on the ITO layer 5, is an organic electroluminescent layer 4 formed from the following stack:
a sublayer 12 of cesium-doped 4,7-diphenyl-1,10-phenanthroline (BPhen) for injecting and transporting electrons;
a sublayer 13 of about 4,7-diphenyl-1,10-phenanthroline (BPhen) with a thickness of about 10 nm, for blocking holes;
an emissive sublayer 11 with a thickness of 20 nm, adapted for emitting green light when a current flows through it, the emittance of this sublayer having a maximum for a wavelength λ=550 nm;
a sublayer 14 of 2,2′,7,7′-tetrakis-(N,N-diphenylamino)-9,9′ spirobifluorene (Spiro-TAD) with a thickness of about 10 nm, for blocking electrons; and
a sublayer 15 of 2,2′,7,7′-tetrakis-(N,N-di-m-methylphenylamino)-9,9′ spirobifluorene (Spiro m-TTB) doped with F4-TCNQ for injecting and transporting holes.

Next, deposited on the organic electroluminescent layer thus obtained is a conducting upper layer 3 of ITO, also with a thickness d₅=150 nm, intended to form the upper electrode of the diode. Owing to the small thickness of ITO, here 150 nm, for the upper conducting layer 3, the transmittance of the upper electrodes is equal to or greater than 85% for the light emitted.

Next, an upper dielectric layer 2 of zinc selenide (ZnSe) is deposited, the thickness d₂ of which is determined as follows. Zinc selenide has an index of 2.6, and therefore substantially greater than 1.6.

In FIG. 2, the curve referenced “d₂”, which gives the variation of reflectivity of the stack of layers 3 and 2 as a function of the thickness d₂ (in nm) of the layer 2 is used to choose a value of d₂=50 nm corresponding approximately to a maximum of this curve. The reflectivity of the stack of these layers is evaluated at a wavelength of 550 nm corresponding approximately to a maximum emittance of the organic electroluminescent layer that was deposited in order to form the diode.

The stack formed on the substrate 7 by the lower dielectric layer 6, the lower conducting layer 5, the organic electroluminescent layer 4, the upper conducting layer 3 and the upper dielectric layer 2 therefore forms an organic electroluminescent diode or array of diodes according to one embodiment of the invention. In the case of an array of diodes, the upper conducting layer 3 and the upper dielectric layer 2 preferably cover all of the diodes. The upper electrode is therefore common to all the diodes and fabrication is facilitated.

Since the stacks of layers 5 and 6 on the one hand, and 3 and 2 on the other, are adjusted for maximum reflection of the light emitted by the diode, the space lying between the lower electrode and the upper electrode of the diode(s) therefore forms an optical cavity and provides a technical effect capable of optimally improving extraction of the emitted light, provided that certain geometric criteria are respected. These criteria will now be specified.

To obtain and optimize this cavity effect, the equations defining the distance z_{low} approximately separating the middle, in the thickness, of the emissive organic sublayer 11 from the lower conducting layer 5, and the distance zᵤₚ approximately separating the middle, in the thickness, of the emissive organic sublayer of the upper conducting layer 3 will now be established. The total thickness d₄ of the organic electroluminescent layer 4 will be deduced from these equations.

The following parameters are considered here:
λ, the wavelength close to the maximum emittance of the emitted light, defined above, and n₄, the average index of the organic electroluminescent layer at this wavelength; and
φ_{low}, the phase shift of a light ray emitted at this wavelength, after reflection of the lower electrode, and φᵤₚ, the phase shift of a light ray emitted at this wavelength after reflection of the upper electrode.

The thickness of the hole injection and/or transport sublayer 12 is chosen approximately so that the distance z_{low} is approximately equal to:

$${z}_{low} = \frac{λ}{2 {n}_{4}} ( q - \frac{{ϕ}_{low}}{2 π} )$$

where q is any integer. This equation expresses the constructive interference between the emitted light and the light reflected off the lower electrode.

The thickness of the electron injection and/or transport sublayer 15 is chosen approximately so that the distance zᵤₚ is approximately equal to:

$${z}_{up} = \frac{λ}{2 {n}_{4}} ( r - \frac{{ϕ}_{up}}{2 π} )$$

where r is any integer. This equation expresses the constructive interference between the emitted light and the light reflected off the upper electrode.

Instead of the arithmetic method of calculating z_{low} and zᵤₚ, a graphical optimization method may be used without departing from the invention. To determine z_{low}, a three-dimensional chart giving the light intensity emitted via the bottom of the diode, through the lower electrode, as a function of d₄ and of z_{low} is therefore used and this chart allows z_{low}=70 nm to be determined. To determine zᵤₚ, a three-dimensional chart giving the light intensity emitted via the top of the diode, through the upper electrode, as a function of d₄ and of zᵤₚ is then used. This chart makes it possible to determine zᵤₚ=70 nm. It should be noted that d₄=z_{low}+zᵤₚ=140 nm makes it possible to obtain maximum emission from the diode, that is to say the maximum extraction.

All the abovementioned constructive interference advantageously prompts extraction of the light through the two electrodes of the diode, thereby improving the luminous efficiency of the diode.

From the z_{low} and zᵤₚ values, the following are deduced:
the thickness of the cesium-doped BPhen sublayer 12 for injecting and transporting electrons, namely 70 nm (z_{low})−10 nm (thickness of the sublayer 13)−10 nm (half-thickness of the emissive sublayer 11)=50 nm; and
the thickness of the Spiro m-TTB sublayer 15 for injecting and transporting holes, namely 70 nm (zᵤₚ)−10 nm (thickness of the sublayer 14)−10 nm (half-thickness of the emissive sublayer 11)=50 nm.

A top-emitting light-emitting diode or array of diodes exhibiting excellent luminous efficiency is obtained thanks to the combination of features specific to the invention that have just been described.

The present invention also applies to an organic electroluminescent diode or display in which the charges are injected via doped organic layers. It is obvious to a person skilled in the art that the invention can be applied to other types of diodes, illumination panels or displays without departing from the scope of the following claims.

1. An organic light-emitting diode capable of emitting light via two opposed faces, comprising:
a transparent or semitransparent substrate (7);
an organic electroluminescent layer (4) capable of emitting light, deposited on this substrate, this layer being interposed between a lower electrode and an upper electrode, each electrode being transparent or semitransparent; and
a lower dielectric layer (6) interposed between the substrate (7) and said lower electrode, which layer is in contact with a lower conducting layer (5) of said lower electrode, and an upper dielectric layer (2) covering said upper electrode, which layer is in contact with an upper conducting layer (3) of said upper electrode,
characterized in that:
the material and the thickness d₂ of said upper dielectric layer (2) and the material and the thickness d₃ of said upper conducting layer (3) are adapted in order for the reflectivity of said emitted light evaluated on this stack of layers (3, 2) to be approximately a maximum; and
the material and the thickness d₆ of said lower dielectric layer (6) and the material and the thickness d₅ of said lower conducting layer (5) are adapted in order for the reflectivity of said emitted light evaluated on this stack of layers (6, 5) to be approximately a maximum.

2. The diode as claimed in claim 1, characterized in that:
the intrinsic transmittance of said light emitted from said lower conducting layer (6) is equal to or greater than 85%.

3. The diode as claimed in claim 2, characterized in that:
the intrinsic transmittance of said light emitted from said upper conducting layer (3) is equal to or greater than 85%.

4. The diode as claimed in any one of the preceding claims, characterized in that the material of the lower dielectric layer (6) and that of the upper dielectric layer (2) have an index greater than 1.6.

5. The diode as claimed in claim 4, characterized in that the lower dielectric layer (6) and the upper dielectric layer (2) have an intrinsic transmittance of the emitted light equal to or greater than 85%.

6. The diode as claimed in any one of the preceding claims, characterized in that the material of said upper conducting layer (3) is identical to the material of said lower conducting layer (5).

7. The diode as claimed in any one of the preceding claims, characterized in that the material of said upper dielectric layer (2) is identical to the material of said lower dielectric layer (6).

8. The diode as claimed in any one of the preceding claims, characterized in that said organic electroluminescent layer (6) comprises an emissive organic sublayer (11) and at least one nonemissive upper organic sublayer (14, 15) which is interposed between the upper electrode (3) and said emissive sublayer (11) and in that the thickness of the nonemissive upper organic sublayer(s) is/are adapted so that the distance zᵤₚ separating approximately the middle, in the thickness, of said emissive organic sublayer (11) from said upper electrode (3) approximately satisfies the equation:
$${z}_{up} = \frac{λ}{2 {n}_{4}} ( r - \frac{{ϕ}_{up}}{2 π} )$$
where r is any integer;
where λ is said wavelength close to a maximum emittance of the emitted light and n₄ is the average index of the organic electroluminescent layer at this wavelength; and
where φᵤₚ is the phase shift of a ray of emitted light, after reflection of the upper electrode.

9. The diode as claimed in claim 8, characterized in that the organic electroluminescent layer (6) comprises an emissive organic sublayer (11) and at least one nonemissive lower organic sublayer (12, 13) which is interposed between the lower electrode (5) and said emissive sublayer (11) and in that the thickness of the nonemissive lower organic sublayer(s) is/are adapted so that the distance z_{low} approximately separating the middle, in the thickness, of said emissive organic sublayer (11) from said lower electrode (5) approximately satisfies the equation:
$${z}_{low} = \frac{λ}{2 {n}_{4}} ( q - \frac{{ϕ}_{low}}{2 π} )$$
where q is any integer;
where λ is said wavelength close to a maximum emittance of the emitted light and n₄ is the average index of the organic electroluminescent layer at this wavelength; and
where φ_{low} is a phase shift of a ray of emitted light, after reflection of the lower electrode.

10. The diode as claimed in any one of the preceding claims, characterized in that the thickness d₄ of said organic electroluminescent layer (4) is adapted so as to obtain constructive interference of the emitted light between the lower electrode and the upper electrode.

11. An image display or an illumination panel comprising a plurality of diodes as claimed in any one of the preceding claims, characterized in that these diodes are supported by the same substrate.
